(19) United States
(12) Patent Application Publication
(10) Pub. No.: US 2025/0107233 A1
(43) Pub. Date: Mar. 27, 2025

(54) DISPLAY DEVICE

(71) Applicant: AUO Corporation, Hsinchu (TW)

(72) Inventors: Yu Chun Yen, Hsinchu (TW); Yu-Sheng Huang, Hsinchu (TW)

(73) Assignee: AUO Corporation, Hsinchu (TW)

(21) Appl. No.: 18/751,347

(22) Filed: Jun. 24, 2024

(30) Foreign Application Priority Data
Sep. 25, 2023 (TW) 112136640

(51) Int. Cl. H01L 27/12; H01L 25/16

(52) U.S. Cl. CPC H10D 86/60; H01L 25/167; H10D 86/441

(57) ABSTRACT

A display device includes a driver substrate and a first light-emitting unit. The driver substrate has a display region and a peripheral region. The first light-emitting unit is disposed on the driver substrate and includes a first microcontroller, a plurality of first pixels, and a plurality of first supplementary pixels. Through the arrangement of the first supplementary pixels, the display region is fully utilized, and improved display quality is achieved.

### CROSS-REFERENCE TO RELATED APPLICATION

This application claims the priority benefit of Taiwan application serial no. 112136640, filed on Sep. 25, 2023. The entirety of the above-mentioned patent application is hereby incorporated by reference herein and made a part of specification.

### BACKGROUND

### Technical Field

The disclosure relates to a display device.

### Description of Related Art

With the rapid advancement of technology, display device technology is undergoing a revolutionary change, from liquid crystal displays to today's micro-light-emitting diode (micro-LED) display devices. Micro-LED display devices offer higher resolution but require lower energy consumption. Therefore, micro-LED display devices may be widely used in various fields, including mobile phones, watches, and other consumer electronic products.

However, with the continuous advancement of display technology, the market's requirements for display quality and appearance design are also growing. An important trend is to achieve superior display quality, including higher color accuracy, better contrast, and more engaging visual effects. At the same time, consumers have also raised higher expectations for the appearance design of displays. Consumers expect narrower bezels, so that they can enjoy more stunning visual effects due to a larger screen ratio. Therefore, in order to satisfy market needs, many manufacturers are committed to developing display devices with better display quality and narrower bezels.

### SUMMARY

The disclosure provides a display device featuring advantages including good display quality and a narrow bezel.

At least one embodiment of the disclosure provides a display device having a driver substrate and a first light-emitting unit. The driver substrate has a display region and a peripheral region. The first light-emitting unit is disposed on the driver substrate and includes a first microcontroller, a plurality of first pixels, and a plurality of first supplementary pixels. The first microcontroller is disposed on the display region and is electrically connected to the driver substrate through a plurality of first connection pads. The plurality of first pixels and the plurality of first supplementary pixels are electrically connected to the first microcontroller and are disposed on the display region. The first pixels are arranged in two rows extending in a second direction in a first direction. The first supplementary pixels are arranged in two other rows extending in the second direction in the first direction. The first microcontroller is disposed between the first pixels in the two rows in the first direction, and the first supplementary pixels in the two other rows are at least partially aligned with the first pixels in the two rows in the first direction.

To sum up, by using the first microcontroller to control the first pixels and the first supplementary pixels, the circuit layout of the display device is simplified, and the adverse effects of the circuit on the display quality is further reduced. Further, the first supplementary pixels are at least partially aligned with the first pixels in the first direction, so that the problem of jagged edges of the display region caused by uneven pixel arrangement is prevented.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic top view of a display device according to a first embodiment of the disclosure.

FIG. 2A is a partially enlarged schematic view of a first light-emitting unit according to the first embodiment of the disclosure.

FIG. 2B is a partially enlarged schematic view of a second light-emitting unit according to the first embodiment of the disclosure.

FIG. 2C is a partially enlarged schematic view of another first light-emitting unit according to the first embodiment of the disclosure.

FIG. 3 is a schematic top view of a display device according to a second embodiment of

the disclosure.

FIG. 4 is a partially enlarged schematic view of a second light-emitting unit according to the second embodiment of the disclosure.

FIG. 5 is a schematic top view of a display device according to a third embodiment of the disclosure.

FIG. 6A is a partially enlarged schematic view of a first light-emitting unit according to the third embodiment of the disclosure.

FIG. 6B is a partially enlarged schematic view of a second light-emitting unit according to the third embodiment of the disclosure.

FIG. 6C is a partially enlarged schematic view of another first light-emitting unit according to the third embodiment of the disclosure.

FIG. 7 is a schematic top view of a display device according to a fourth embodiment of the disclosure.

FIG. 8 is a schematic top view of a display device according to a fifth embodiment of the disclosure.

FIG. 9 is a schematic top view of a display device according to a sixth embodiment of the disclosure.

### DESCRIPTION OF THE EMBODIMENTS

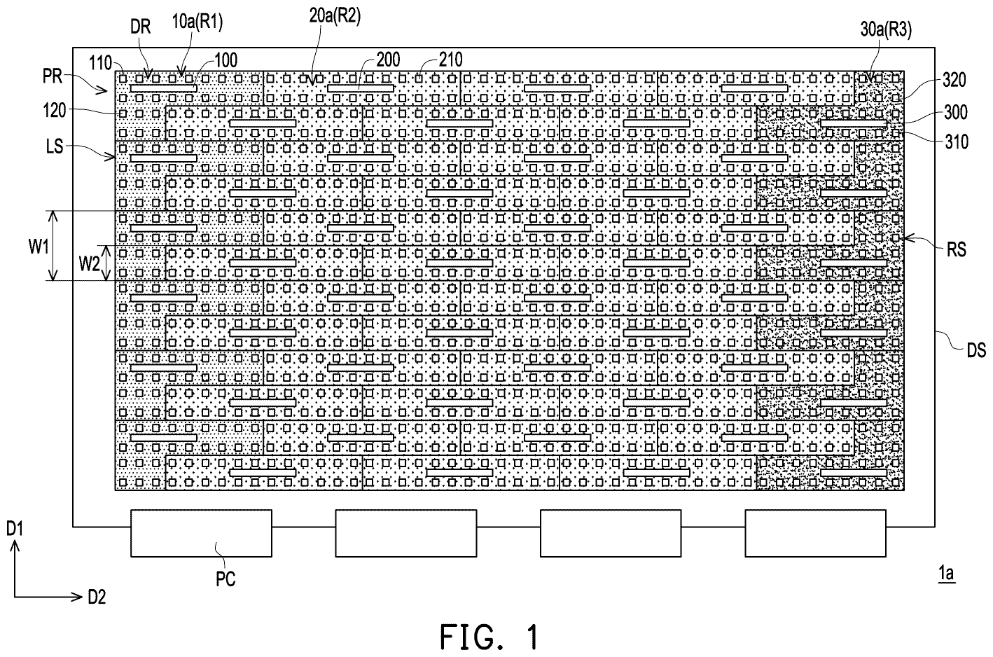

FIG. 1 is a schematic top view of a display device 1a according to a first embodiment of the disclosure. It should be noted that in FIG. 1, various traces in the light-emitting unit are omitted and the pixels in the light-emitting unit are simplified into rectangles. With reference to FIG. 1, the display device 1a includes a driver substrate DS and a plurality of first light-emitting units 10a. In this embodiment, the display device 1a further includes a plurality of second light-emitting units 20a, a plurality of third light-emitting units 30a, and a plurality of flexible circuit boards PC.

The driver substrate DS has a display region DR and a peripheral region PR. The peripheral region PR is disposed on at least one side of the display region DR. The driver substrate DS includes a substrate and electronic components (e.g., transistors, capacitors, resistors, etc., which are not shown separately in the figure) located on the substrate. The substrate is, for example, a rigid substrate, and a material of the substrate may be glass, quartz, an organic polymer, an opaque/reflective material (e.g., a conductive material, metal, a wafer, ceramics, or other suitable materials), or other suitable materials. However, the disclosure is not limited thereto, and in other embodiments, the substrate may also be a flexible substrate or a stretchable substrate. For instance, materials of the flexible substrate and the stretchable substrate include, for example, polyimide (PI), polydimethylsiloxane (PDMS), polyethylene terephthalate (PET), polyethylene naphthalate (PEN), polyester (PES), polymethylmethacrylate (PMMA), polycarbonate (PC), polyurethane (PU), or other suitable materials.

The display region DR includes a plurality of first control regions R1, a plurality of second control regions R2, and a plurality of third control regions R3. The first light-emitting units 10a, the second light-emitting units 20a, and the third light-emitting units 30a are respectively disposed on the first control regions R1, the second control regions R2, and the third control regions R3. In this embodiment, the first control regions R1 and the third control regions R3 are L-shaped, where the first control regions R1 and the third control regions R3 are L-shaped in different directions (for example, rotated 180 degrees). The second control regions R2 are in the shape of straight bars. The first control regions R1 and the third control regions R3 have similar shapes. A width W1 of each of the first control regions R1 and the third control regions R3 in a first direction D1 is twice a width W2 of each of the second control regions R2 in the first direction D1.

The first control regions R1 are arranged in a row in the first direction D1, and the third control regions R3 are also arranged in a row in the first direction D1. The first control regions R1 and the third control regions R3 are respectively located at a first side LS of the display region DR and a second side RS opposite to the first side LS. In this embodiment, in a second direction D2 perpendicular to the first direction D1, two rows of second control regions R2 are disposed between each first control region R1 and a corresponding third control region R3.

In this embodiment, the plurality of first control regions R1 are aligned in the first direction D1 at a boundary between the display region DR and the peripheral region PR (e.g., the first side LS of the display region DR). The plurality of third control regions R3 are aligned in the first direction D1 at the boundary between the display region DR and the peripheral region PR (e.g., the second side RS of the display region DR).

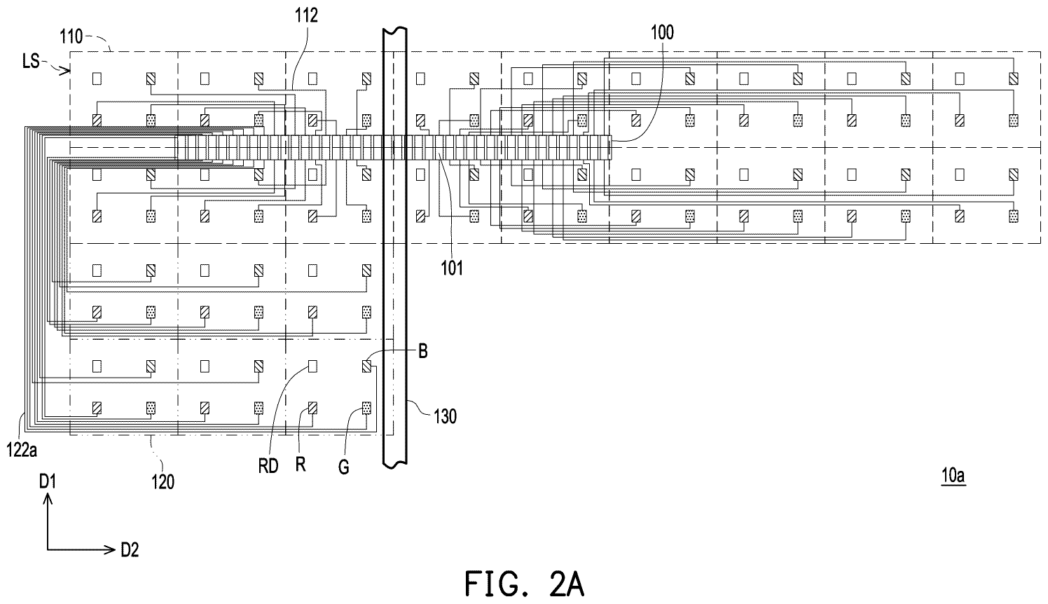

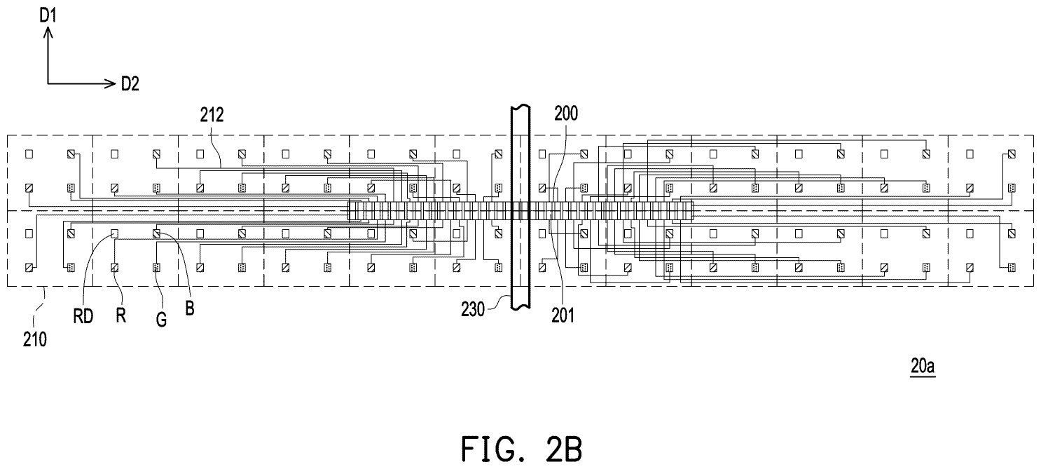

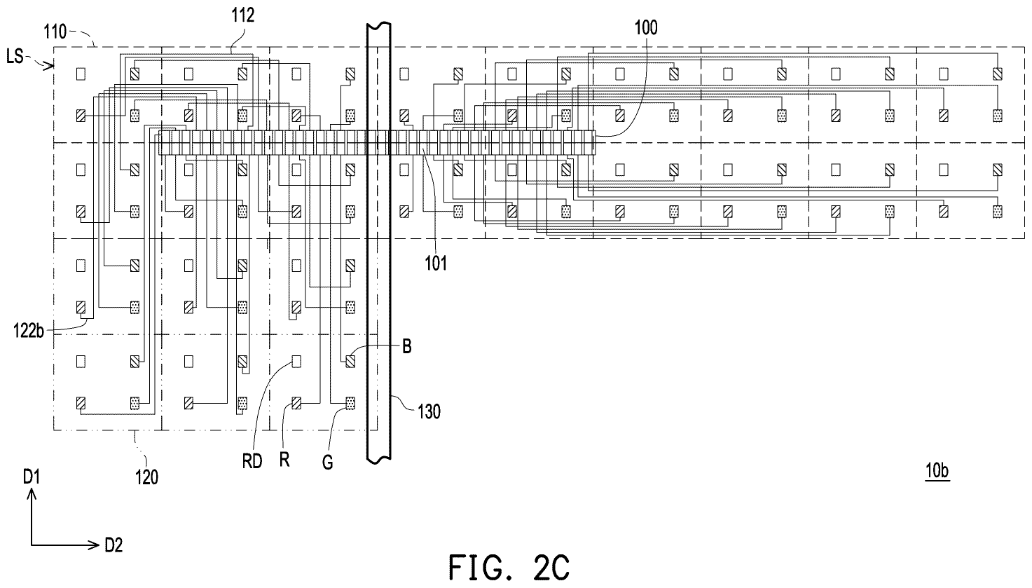

FIG. 2A is a partially enlarged schematic view of one first light-emitting unit 10a according to the first embodiment of the disclosure. It should be noted that in FIG. 2A, a first microcontroller 100 is shown in a perspective manner, thereby showing a first connection pad 101 below the first microcontroller 100. With reference to FIG. 1 and FIG. 2A together, the first light-emitting units 10a are disposed on the first control regions R1 of the display region DR of the driver substrate DS. The plurality of first light-emitting units 10a are arranged in the first direction D1.

Each of the first light-emitting units 10a includes the first microcontroller 100, a plurality of first pixels 110, and a plurality of first supplementary pixels 120. In this embodiment, each of the first light-emitting units 10a further includes a plurality of first traces 112 and a plurality of first supplementary traces 122a. In this embodiment, in each of the first light-emitting units 10a, the first microcontroller 100, the first pixels 110, the first supplementary pixels 120, the first traces 112, and the first supplementary traces 122a are disposed on a corresponding one among the first control regions R1 of the display region DR. In this embodiment, the number of the first pixels 110 is greater than the number of the first supplementary pixels 120.

The first microcontroller 100 is electrically connected to the driver substrate DS through a plurality of first connection pads 101. The first microcontroller 100 includes a micro integrated circuit (micro IC). In some embodiments, the first microcontroller 100 is bonded to the driver substrate DS through a wafer bonding process. Conductive glue, solder, or other suitable conductive bonding components, for example, are included between the first microcontroller 100 and the first connection pads 101.

In some embodiments, the plurality of first microcontrollers 100 arranged in a column in the first direction D1 are connected in series via a circuit structure 130 extending in the first direction D1. The circuit structure 130 includes, for example, a plurality of signal lines. In FIG. 2A, the specific circuit layout in the circuit structure 130 is omitted.

Each of the first pixels 110 and the first supplementary pixels 120 includes a plurality of light-emitting elements (e.g., a red light-emitting diode R, a blue light-emitting diode B, and a green light-emitting diode G). The red light-emitting diode R, the blue light-emitting diode B, and the green light-emitting diode G are electrically connected to the driver substrate DS through pads (not shown separately in the figure). The red light-emitting diode R, the blue light-emitting diode B, and the green light-emitting diode G may be light-emitting diodes of any form, such as horizontal light-emitting diodes, vertical light-emitting diodes, or other types of light-emitting diodes.

In this embodiment, each of the first pixels 110 and the first supplementary pixels 120 further includes a redundant spare electrode RD. During a repair process, a repaired light-emitting diode may be bonded to the redundant spare electrode RD.

The first pixels 110 are arranged in two rows extending in the second direction D2 in the first direction D1. The first supplementary pixels 120 are arranged in two other rows extending in the second direction D2 in the first direction D1. The first microcontroller 100 is disposed between the first pixels 110 in the two rows in the first direction D1, and the first supplementary pixels 120 in the two other rows are at least partially aligned with the first pixels 110 in the two rows in the first direction D1. In each of the first light-emitting units 10a, a vertical projection of the first microcontroller 100 on the driver substrate DS does not overlap with vertical projections of the first pixels 110 and the first supplementary pixels 120 on the driver substrate DS.

In this embodiment, the first traces 112 are completely disposed in the display region DR and electrically connect the first microcontroller 100 to the first pixels 110 in the two rows. In this embodiment, each light-emitting element (e.g., the red light-emitting diode R, the blue light-emitting diode B, and the green light-emitting diode G) in each first pixel 110 is electrically connected to the first connection pad 101 of the first microcontroller 100 through one corresponding first trace 112.

In this embodiment, the first supplementary traces 122a electrically connect the first microcontroller 100 to the first supplementary pixels 120 in the two other rows. In the embodiment of FIG. 2A, at least a portion of the first supplementary traces 122a extend from the first microcontroller 100 in the display region DR through the first side LS of the display region DR to the peripheral region PR and then extends from the peripheral region PR through the first side LS of the display region DR again to the first supplementary pixels 120 in the two other rows in the display region DR. The first supplementary traces 122a are turned in the peripheral region PR so as to electrically connect the first supplementary pixels 120 and the first microcontroller 100. In the embodiment of FIG. 2A, the first supplementary traces 122a extend from the display region DR to the peripheral region PR, but the disclosure is not limited thereto. In other embodiments, the first supplementary traces 122a are completely disposed in the display region DR, as shown by first supplementary traces 122b of a first light-emitting unit 10b in FIG. 2C.

In some embodiments, one of the electrodes of each of the red light-emitting diode R, the blue light-emitting diode B, and the green light-emitting diode G in the first light-emitting unit 10a is electrically connected to the first microcontroller 100 through the first trace 112 or the first supplementary trace 122a, and the other electrode is electrically connected to a common electrode.

In this embodiment, by using the first microcontroller 100 to control the first pixels 110 and the first supplementary pixels 120, the circuit layout of the display device 1a may be simplified, and the adverse effects of the circuit on the display quality may be further reduced. To be specific, compared to the arrangement of arranging the first microcontroller 100 in the peripheral region PR, the first microcontroller 100 is disposed in the display region DR in this embodiment, so that trace lengths between the first microcontroller 100 and the first pixels 110 and between the first microcontroller 100 and the first supplementary pixels 120 may be reduced. In this embodiment, by arranging the microcontrollers (including the first microcontrollers 100, second microcontrollers 200, and third microcontrollers 300) in an alternating manner (for example, arranging in an alternating manner in the first direction D1 and/or the second direction D2), the traces may be better dispersed to make more efficient use of the circuit layout space. Further, the negative impact of the microcontrollers on a display screen may be lowered.

In this embodiment, by designing the first supplementary traces 122a and the first supplementary pixels 120, uneven pixel arrangement at an edge of the display region DR may be avoided. To be specific, without the design of the first light-emitting unit 10a, the first side LS of the display region DR may have a jagged edge (such as the left edge formed by connecting a row of second control regions R2 closest to the first side LS in FIG. 1). In order to prevent the jagged edges from affecting a display image, a bezel is usually set to cover the jagged edges. In this embodiment, the problem of jagged edges on the display screen may be avoided by using the first supplementary traces 122a and the first supplementary pixels 120 of the first light-emitting unit 10a. The aforementioned bezel for shielding the jagged edges may then be omitted, and the advantage of a narrow bezel is obtained.

Each of the third light-emitting units 30a includes the third microcontroller 300, a plurality of third pixels 310, and a plurality of third supplementary pixels 320. In this embodiment, each of the third light-emitting units 30a further includes a plurality of third traces (not shown separately in the figure) and a plurality of third supplementary traces (not shown separately in the figure). The third light-emitting unit 30a has an arrangement similar to that of the first light-emitting unit 10a in FIG. 2A (or the first light-emitting unit 10b in FIG. 2C). The difference therebetween is that the third supplementary pixels 320 of the third light-emitting unit 30a are disposed above the third pixels 310, while the first supplementary pixels 120 of the first light-emitting unit 10a (or the first light-emitting unit 10b in FIG. 2C) are disposed below the first pixels 110. Further, the third supplementary traces of the third light-emitting unit 30a may pass through the second side RS of the display region DR to extend into the peripheral region PR, or the third supplementary traces of the third light-emitting unit 30a may be completely disposed in the display region DR.

FIG. 2B is a partially enlarged schematic view of one second light-emitting unit 20a according to the first embodiment of the disclosure. It should be noted that in FIG. 2B, the second microcontroller 200 is shown in a perspective manner, thereby showing a second connection pad 201 below the second microcontroller 200. With reference to FIG. 1 and FIG. 2B together, the second light-emitting units 20a are disposed on the second control regions R2 of the display region DR of the driver substrate DS. The plurality of second light-emitting units 20a are arranged in the first direction D1. In this embodiment, the plurality of second light-emitting units 20a are arranged in an array in the first direction D1 and the second direction D2.

Each of the second light-emitting units 20a includes the second microcontroller 200 and a plurality of second pixels 210. In this embodiment, each of the second light-emitting units 20a further includes a plurality of second traces 212. In this embodiment, in each of the second light-emitting units 20a, the second microcontroller 200, the second pixels 200, and the first traces 112 are disposed on a corresponding one among the second control regions R2 of the display region DR.

The second microcontroller 200 is electrically connected to the driver substrate DS through a plurality of second connection pads 201. The second microcontroller 200 includes a micro integrated circuit. In some embodiments, the second microcontroller 200 is bonded to the driver substrate DS through a wafer bonding process. Conductive glue, solder, or other suitable conductive bonding components, for example, are included between the second microcontroller 200 and the second connection pads 201.

In this embodiment, the microcontrollers in each column are arranged in an alternating manner with the microcontrollers in the adjacent column in the first direction D1. For instance, in the embodiment of FIG. 1, in the left region of the display region DR, the first microcontrollers 100 of the first light-emitting units 10a and the second microcontrollers 200 of the second light-emitting units 20a are arranged in an alternating manner in the first direction D1. In the middle region of the display region DR, the second microcontrollers 200 are arranged in an alternating manner in the first direction D1 and/or the second direction D2. In the right region of the display region DR, the second microcontrollers 200 of the second light-emitting units 20a and the third microcontrollers 300 of the third light-emitting units 30a are arranged in an alternating manner in the first direction D1.

In some embodiments, the second microcontrollers 200 arranged in a column in the first direction D1 are connected in series via a circuit structure 230 extending in the first direction D1. The circuit structure 230 includes, for example, a plurality of signal lines. In FIG. 2B, the specific circuit layout in the circuit structure 230 is omitted.

Each of the second pixels 210 includes a plurality of light-emitting elements (e.g., the red light-emitting diode R, the blue light-emitting diode B, and the green light-emitting diode G). The red light-emitting diode R, the blue light-emitting diode B, and the green light-emitting diode G are electrically connected to the driver substrate DS through pads (not shown separately in the figure). In this embodiment, each of the second pixels 210 further includes the redundant spare electrode RD.

In each of the second light-emitting units 20a, the second pixels 210 are arranged in two rows extending in the second direction D2 in the first direction D1, and the second microcontroller 200 is disposed between the second pixels 210 in the two rows in the first direction D1. The vertical projection of the first microcontroller 100 on the driver substrate DS does not overlap with vertical projections of the second pixels 210 on the driver substrate DS.

In this embodiment, the second traces 212 are completely disposed in the display region DR and electrically connect the second microcontroller 200 to the second pixels 210 in the two rows. In this embodiment, each light-emitting element (e.g., the red light-emitting diode R, the blue light-emitting diode B, and the green light-emitting diode G) in each second pixel 210 is electrically connected to the second connection pad 201 of the second microcontroller 200 through one corresponding second trace 212.

In some embodiments, one of the electrodes of each of the red light-emitting diode R, the blue light-emitting diode B, and the green light-emitting diode G in the second light-emitting unit 20a is electrically connected to the second microcontroller 200 through the second trace 212, and the other electrode is electrically connected to the common electrode. It should be noted that the red light-emitting diode R, the blue light-emitting diode B, and the green light-emitting diode G in each of the second pixels 210 are connected to the corresponding second connection pads 201 of the second microcontroller 200. However, the arrangement order of the second connection pads 201 can be adjusted according to needs, and the arrangement order of the second connection pads 201 is not limited in the disclosure.

With reference to FIG. 1, FIG. 2A, and FIG. 2B, a plurality of flexible circuit boards PC are located at the edge of the driver substrate DS and are electrically connected to the first microcontrollers 100, the second microcontrollers 200, and the third microcontrollers 300. The first microcontrollers 100, the second microcontrollers 200, or the third microcontrollers 300 arranged in the same column in the first direction D1 are electrically connected to the same flexible circuit board PC. For instance, the first microcontrollers 100 arranged in the same column in the first direction D1 are electrically connected to the same flexible circuit board PC through the circuit structure 130. The second microcontrollers 200 arranged in another column in the first direction D1 are electrically connected to another flexible circuit board PC through the circuit structure 230. The number of flexible circuit boards may be adjusted according to actual needs.

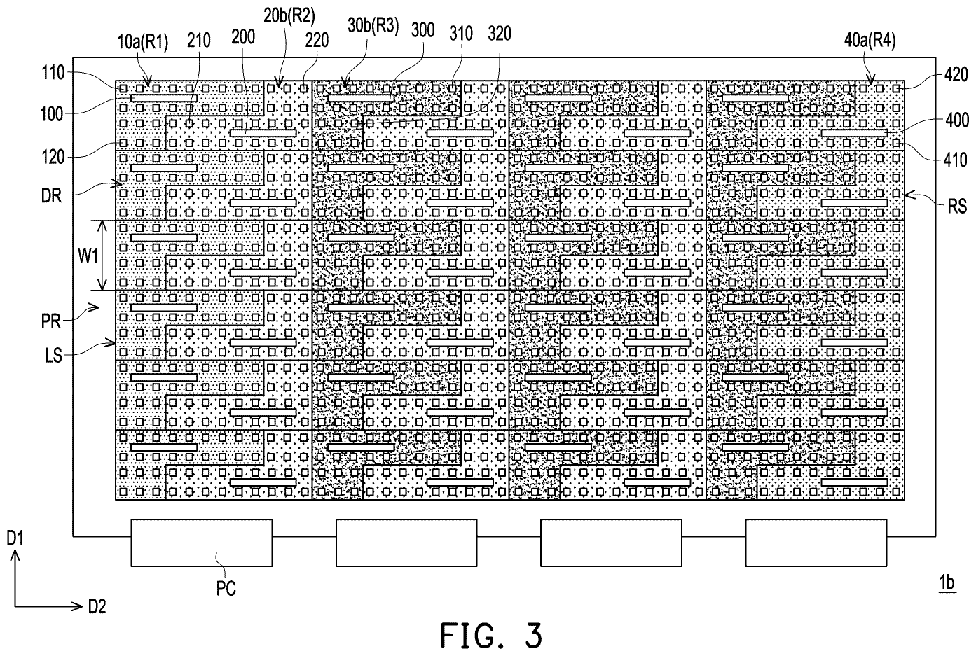

FIG. 3 is a schematic top view of a display device 1b according to a second embodiment of the disclosure. The display device 1b is different from the display device 1a of the first embodiment in that shapes of a portion of control regions within the display region DR are different.

With reference to FIG. 3, in this embodiment, the display region DR of the display device 1b includes a plurality of first control regions R1, a plurality of second control regions R2, a plurality of third control regions R3, and a plurality of fourth control regions R4.

In this embodiment, the first control regions R1 are arranged in a column in the first direction D1 at the first side LS of the display region DR, and the fourth control regions R4 are arranged in another column in the first direction D1 at the second side RS of the display region DR. The second control regions R2 and the third control regions R3 are disposed between the first control regions R1 and the fourth control regions R4. The second control regions R2 are arranged in a plurality of columns in the first direction D1, and the third control regions R3 are arranged in another plurality of column in the first direction D1. The second control regions R2 and the third control regions R3 are arranged in an alternating manner in the second direction D2.

In this embodiment, the first control regions R1, the second control regions R2, the third control regions R3, and the fourth control regions R4 are all L-shaped. The first control regions R1, the second control regions R2, the third control regions R3, and the fourth control regions R4 have similar shapes. In this embodiment, the widths W1 of the first control regions R1, the second control regions R2, the third control regions R3, and the fourth control regions R4 in the first direction D1 are equal to each other.

The first light-emitting units 10a are disposed on the first control regions R1, and each of the first light-emitting units 10a includes the first microcontroller 100, the first pixels 110, and the first supplementary pixels 120. In this embodiment, each of the first light-emitting units 10a further includes the first traces (with reference to FIG. 2A or FIG. 2C) and the first supplementary traces (with reference to the first supplementary traces 122a in FIG. 2A or the first supplementary traces 122b in FIG. 2C).

Fourth light-emitting units 40a are disposed on the fourth control regions R1, and each of the fourth light-emitting units 40a includes a fourth microcontroller 400, a plurality of fourth pixels 410, and a plurality of fourth supplementary pixels 420. In this embodiment, each of the fourth light-emitting units 40a further includes a plurality of fourth traces (not shown separately in the figure) and a plurality of fourth supplementary traces (not shown separately in the figure). The fourth light-emitting unit 40a has an arrangement similar to that of the first light-emitting unit 10a in FIG. 2A (or the first light-emitting unit 10b in FIG. 2C). The difference therebetween is that the fourth supplementary pixels 420 of the fourth light-emitting unit 40a are disposed above the fourth pixels 410, while the first supplementary pixels 120 of the first light-emitting unit 10a (or the first light-emitting unit 10b in FIG. 2C) are disposed below the first pixels 110.

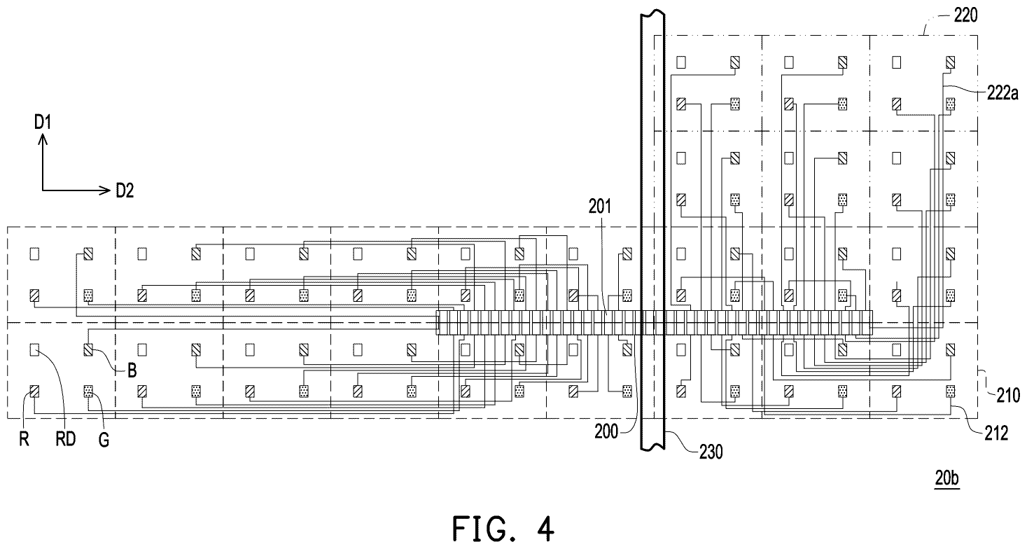

FIG. 4 is a partially enlarged schematic view of a second light-emitting unit 20b according to the second embodiment of the disclosure. With reference to FIG. 3 and FIG. 4, second light-emitting units 20b are disposed on the second control regions R2, and each of the second light-emitting units 20b includes a second microcontroller 200, a plurality of second pixels 210, and a plurality of second supplementary pixels 220. In this embodiment, each of the second light-emitting units 20b further includes a plurality of second traces 212 and a plurality of second supplementary traces 222a. In this embodiment, the number of the second pixels 210 is greater than the number of the second supplementary pixels 220.

The second microcontroller 200 is electrically connected to the driver substrate DS through a plurality of second connection pads 201. In some embodiments, the second microcontroller 200 is bonded to the driver substrate DS through a wafer bonding process. Conductive glue, solder, or other suitable conductive bonding components, for example, are included between the second microcontroller 200 and the second connection pads 201.

In some embodiments, the second microcontrollers 200 arranged in a column in the first direction D1 are connected in series via a circuit structure 230 extending in the first direction D1. The circuit structure 230 includes, for example, a plurality of signal lines. In FIG. 4, the specific circuit layout in the circuit structure 230 is omitted.

Each of the second pixels 210 and the second supplementary pixels 220 includes a plurality of light-emitting elements (e.g., a red light-emitting diode R, a blue light-emitting diode B, and a green light-emitting diode G). The red light-emitting diode R, the blue light-emitting diode B, and the green light-emitting diode G are electrically connected to the driver substrate DS through pads (not shown separately in the figure). The red light-emitting diode R, the blue light-emitting diode B, and the green light-emitting diode G may be light-emitting diodes of any form, such as horizontal light-emitting diodes, vertical light-emitting diodes, or other types of light-emitting diodes.

In this embodiment, each of the second pixels 210 and the second supplementary pixels 220 further includes a redundant spare electrode RD. During a repair process, a repaired light-emitting diode may be bonded to the redundant spare electrode RD.

The second pixels 210 are arranged in two rows extending in the second direction D2 in the first direction D1. The second supplementary pixels 220 are arranged in two other rows extending in the second direction D2 in the first direction D1. The second microcontroller 200 is disposed between the second pixels 210 in the two rows in the first direction D1, and the second supplementary pixels 220 in the two other rows are at least partially aligned with the second pixels 210 in the two rows in the first direction D1. In each of the second light-emitting units 20b, a vertical projection of the second microcontroller 200 on the driver substrate DS does not overlap with vertical projections of the second pixels 210 and the second supplementary pixels 220 on the driver substrate DS.

In this embodiment, the second traces 212 are completely disposed in the display region DR and electrically connect the second microcontroller 200 to the second pixels 210 in the two rows. In this embodiment, each light-emitting element (e.g., the red light-emitting diode R, the blue light-emitting diode B, and the green light-emitting diode G) in each second pixel 210 is electrically connected to the second connection pad 201 of the second microcontroller 200 through one corresponding second trace 212.

In this embodiment, the second supplementary traces 222a are completely disposed in the display region DR and electrically connect the second microcontroller 200 to the second supplementary pixels 220 in the two rows. In this embodiment, each light-emitting element (e.g., the red light-emitting diode R, the blue light-emitting diode B, and the green light-emitting diode G) in each second supplementary pixel 220 is electrically connected to the second connection pad 201 of the second microcontroller 200 through one corresponding second supplementary trace 222a.

Each of the third light-emitting units 30b includes a third microcontroller 300, a plurality of third pixels 310, and a plurality of third supplementary pixels 320. In this embodiment, each of the third light-emitting units 30b further includes a plurality of third traces (not shown separately in the figure) and a plurality of third supplementary traces (not shown separately in the figure). The third light-emitting unit 30b has an arrangement similar to that of the second light-emitting unit 20b of FIG. 4. The difference therebetween is that the third supplementary pixels 320 of the third light-emitting unit 30b are disposed below the third pixels 310, while the second supplementary pixels 220 of the second light-emitting unit 20b are disposed above the second pixels 210. The arrangement of the third light-emitting unit 30b is similar to that of the first light-emitting unit 10b of FIG. 2C.

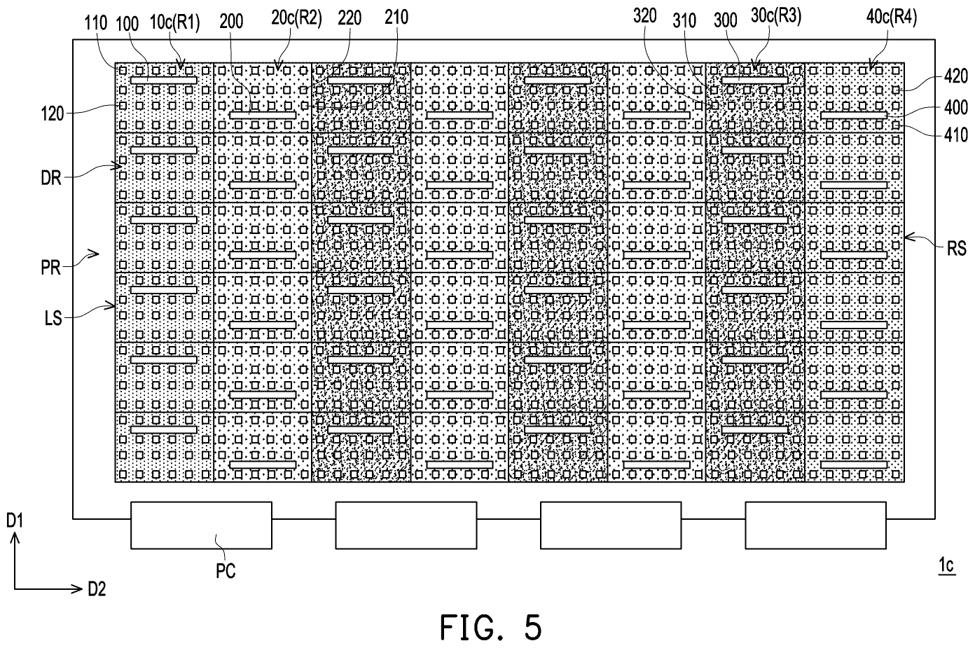

FIG. 5 is a schematic top view of a display device 1c according to a third embodiment of the disclosure. The display device 1c is different from the display device 1a of the first embodiment in that the shapes of a portion of the control regions within the display region DR are different.

With reference to FIG. 5, in this embodiment, the display region DR of the display device 1c includes a plurality of first control regions R1, a plurality of second control regions R2, a plurality of third control regions R3, and a plurality of fourth control regions R4.

In this embodiment, the first control regions R1 are arranged in a column in the first direction D1 at the first side LS of the display region DR, and the fourth control regions R4 are arranged in another column in the first direction D1 at the second side RS of the display region DR. The second control regions R2 and the third control regions R3 are disposed between the first control regions R1 and the fourth control regions R4. The second control regions R2 are arranged in a plurality of columns in the first direction D1, and the third control regions R3 are arranged in another plurality of column in the first direction D1. The second control regions R2 and the third control regions R3 are arranged in an alternating manner in the second direction D2.

In this embodiment, the first control regions R1, the second control regions R2, the third control regions R3, and the fourth control regions R4 are all rectangular. The first control regions R1, the second control regions R2, the third control regions R3, and the fourth control regions R4 have similar shapes.

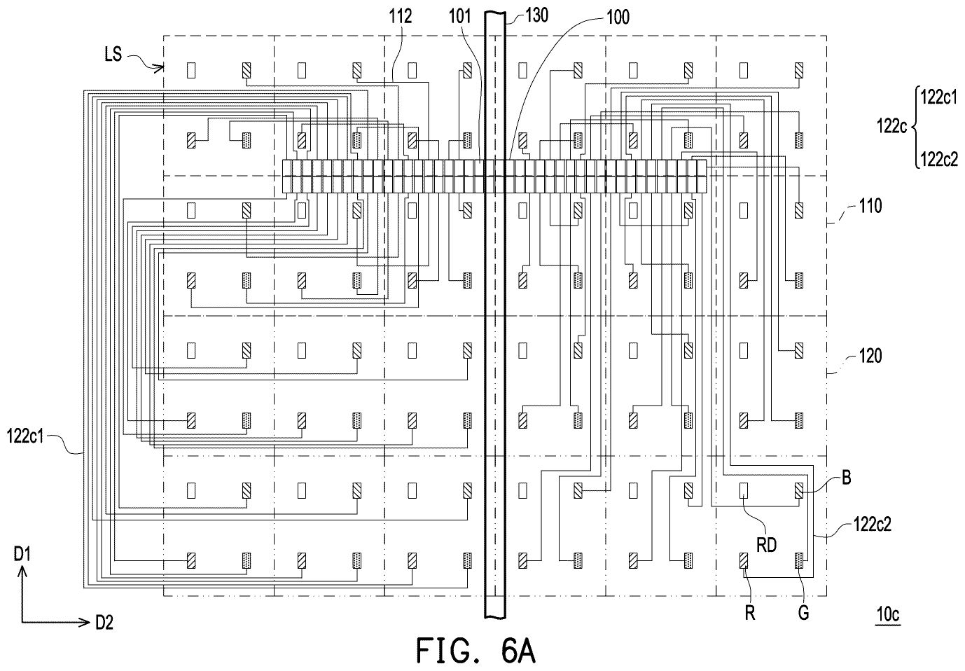

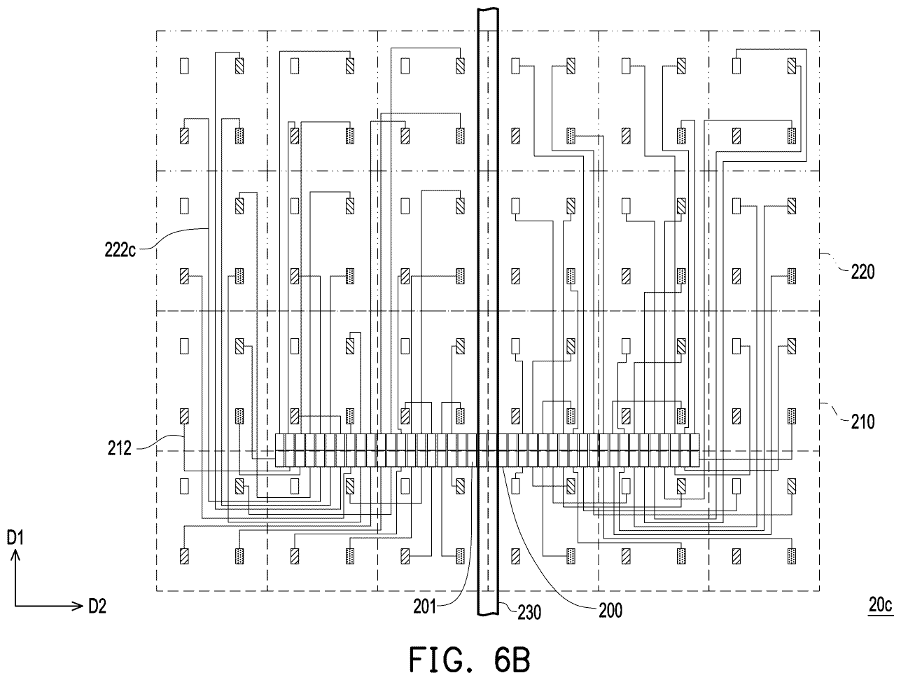

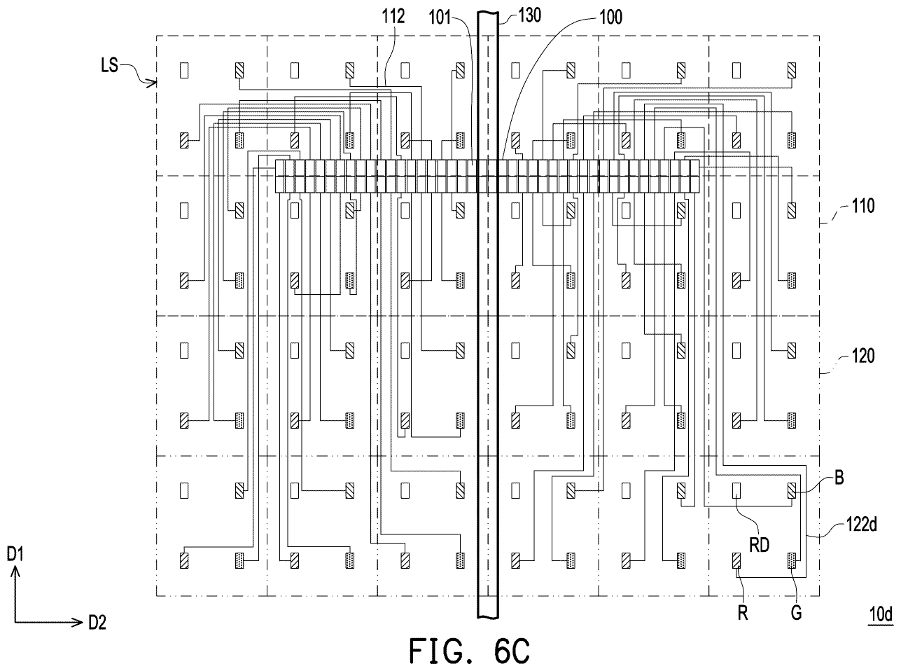

FIG. 6A is a partially enlarged schematic view of a first light-emitting unit 10c according to the first embodiment of the disclosure. It should be noted that in FIG. 6A, a first microcontroller 100 is shown in a perspective manner, thereby showing a first connection pad 101 below the first microcontroller 100. With reference to FIG. 5 and FIG. 6A together, the first light-emitting units 10c are disposed on the first control regions R1 of the display region DR of the driver substrate DS. The plurality of first light-emitting units 10a are arranged in the first direction D1.

Each of the first light-emitting units 10c includes the first microcontroller 100, a plurality of first pixels 110, and a plurality of first supplementary pixels 120. In this embodiment, each of the first light-emitting units 10c further includes a plurality of first traces 112 and a plurality of first supplementary traces 122c. In this embodiment, in each of the first light-emitting units 10c, the first microcontroller 100, the first pixels 110, the first supplementary pixels 120, the first traces 112, and the first supplementary traces 122c are disposed on a corresponding one among the first control regions R1 of the display region DR. In this embodiment, the number of the first pixels 110 is equal to the number of the first supplementary pixels 120.

In some embodiments, the first microcontrollers 100 arranged in a column in the first direction D1 are connected in series via a circuit structure 130 extending in the first direction D1. The circuit structure 130 includes, for example, a plurality of signal lines. In FIG. 6A, the specific circuit layout in the circuit structure 130 is omitted.

The first pixels 110 are arranged in two rows extending in the second direction D2 in the first direction D1. The first supplementary pixels 120 are arranged in two other rows extending in the second direction D2 in the first direction D1. The first microcontroller 100 is disposed between the first pixels 110 in the two rows in the first direction D1, and the first supplementary pixels 120 in the two other rows are at least partially aligned with the first pixels 110 in the two rows in the first direction D1. In each of the first light-emitting units 10c, a vertical projection of the first microcontroller 100 on the driver substrate DS does not overlap with vertical projections of the first pixels 110 and the first supplementary pixels 120 on the driver substrate DS.

In this embodiment, the first traces 112 are completely disposed in the display region DR and electrically connect the first microcontroller 100 to the first pixels 110 in the two rows. In this embodiment, each light-emitting element (e.g., the red light-emitting diode R, the blue light-emitting diode B, and the green light-emitting diode G) in each first pixel 110 is electrically connected to the first connection pad 101 of the first microcontroller 100 through one corresponding first trace 112.

In this embodiment, the first supplementary traces 122c electrically connect the first microcontroller 100 to the first supplementary pixels 120 in the two other rows. In the embodiment of FIG. 6A, at least a portion of the first supplementary traces 122c1 extend from the first microcontroller 100 in the display region DR through the first side LS of the display region DR to the peripheral region PR and then extends from the peripheral region PR through the first side LS of the display region DR again to the first supplementary pixels 120 in the two other rows in the display region DR. The first supplementary traces 122c1 are turned in the peripheral region PR so as to electrically connect the first supplementary pixels 120 and the first microcontroller 100. Another portion of the first supplementary traces 122c2 are completely disposed in the display region DR and electrically connect another portion of the first supplementary pixels 120 and the first microcontroller 100. It should be noted that the red light-emitting diode R, the blue light-emitting diode B, and the green light-emitting diode G in each of the first pixels 110 and the first supplementary pixels 120 are connected to the corresponding first connection pads 101 of the second microcontroller 100. However, the arrangement order of the first connection pads 101 can be adjusted according to needs, and the arrangement order of the first connection pads 101 is not limited in the disclosure.

In the embodiment of FIG. 6A, a portion of the first supplementary traces 122c1 extend from the display region DR to the peripheral region PR, but the disclosure is not limited thereto. In other embodiments, all of the first supplementary traces 122c are completely disposed in the display region DR, as shown by first supplementary traces 122d of a first light-emitting unit 10d in FIG. 6C.

Each of the fourth light-emitting units 40c includes a fourth microcontroller 400, a plurality of fourth pixels 410, and a plurality of fourth supplementary pixels 420. In this embodiment, each of the fourth light-emitting units 40c further includes a plurality of fourth traces (not shown separately in the figure) and a plurality of fourth supplementary traces (not shown separately in the figure). The fourth light-emitting unit 40c has an arrangement similar to that of the first light-emitting unit 10c in FIG. 6A (or the first light-emitting unit 10d in FIG. 6C). The difference therebetween is that the fourth supplementary pixels 420 of the fourth light-emitting unit 40c are disposed above the fourth pixels 410, while the first supplementary pixels 120 of the first light-emitting unit 10c (or the first light-emitting unit 10d in FIG. 6C) are disposed below the first pixels 110.

FIG. 6B is a partially enlarged schematic view of a second light-emitting unit 20c according to the second embodiment of the disclosure. With reference to FIG. 5 and FIG. 6B, second light-emitting units 20c are disposed on the second control regions R2, and each of the second light-emitting units 20c includes a second microcontroller 200, a plurality of second pixels 210, and a plurality of second supplementary pixels 220. In this embodiment, each of the second light-emitting units 20c further includes a plurality of second traces 212 and a plurality of second supplementary traces 222c. In this embodiment, the number of the second pixels 210 is equal to the number of the second supplementary pixels 220.

The second microcontroller 200 is electrically connected to the driver substrate DS through a plurality of second connection pads 201. In some embodiments, the second microcontroller 200 is bonded to the driver substrate DS through a wafer bonding process. Conductive glue, solder, or other suitable conductive bonding components, for example, are included between the second microcontroller 200 and the second connection pads 201.

In some embodiments, the plurality of second microcontrollers 200 arranged in a column in the first direction D1 are connected in series via a circuit structure 230 extending in the first direction D1. The circuit structure 230 includes, for example, a plurality of signal lines. In FIG. 6B, the specific circuit layout in the circuit structure 230 is omitted.

The second pixels 210 are arranged in two rows extending in the second direction D2 in the first direction D1. The second supplementary pixels 220 are arranged in two other rows extending in the second direction D2 in the first direction D1. The second microcontroller 200 is disposed between the second pixels 210 in the two rows in the first direction D1, and the second supplementary pixels 220 in the two other rows are at least partially aligned with the second pixels 210 in the two rows in the first direction D1. In each of the second light-emitting units 20c, a vertical projection of the second microcontroller 200 on the driver substrate DS does not overlap with vertical projections of the second pixels 210 and the second supplementary pixels 220 on the driver substrate DS.

In this embodiment, the second traces 212 are completely disposed in the display region DR and electrically connect the second microcontroller 200 to the second pixels 210 in the two rows. In this embodiment, each light-emitting element (e.g., the red light-emitting diode R, the blue light-emitting diode B, and the green light-emitting diode G) in each second pixel 210 is electrically connected to the second connection pad 201 of the second microcontroller 200 through one corresponding second trace 212.

In this embodiment, the second supplementary traces 222c are completely disposed in the display region DR and electrically connect the second microcontroller 200 to the second supplementary pixels 220 in the two rows. In this embodiment, each light-emitting element (e.g., the red light-emitting diode R, the blue light-emitting diode B, and the green light-emitting diode G) in each second supplementary pixel 220 is electrically connected to the second connection pad 201 of the second microcontroller 200 through one corresponding second supplementary trace 222c. It should be noted that the red light-emitting diode R, the blue light-emitting diode B, and the green light-emitting diode G in each of the second pixels 210 and the second supplementary pixels 220 are connected to the corresponding second connection pads 201 of the second microcontroller 200. However, the arrangement order of the second connection pads 201 can be adjusted according to needs, and the arrangement order of the second connection pads 201 is not limited in the disclosure.

Each of the third light-emitting units 30c includes a third microcontroller 300, a plurality of third pixels 310, and a plurality of third supplementary pixels 320. In this embodiment, each of the third light-emitting units 30c further includes a plurality of third traces (not shown separately in the figure) and a plurality of third supplementary traces (not shown separately in the figure). The third light-emitting unit 30c has an arrangement similar to that of the first light-emitting unit 10d of FIG. 6C.

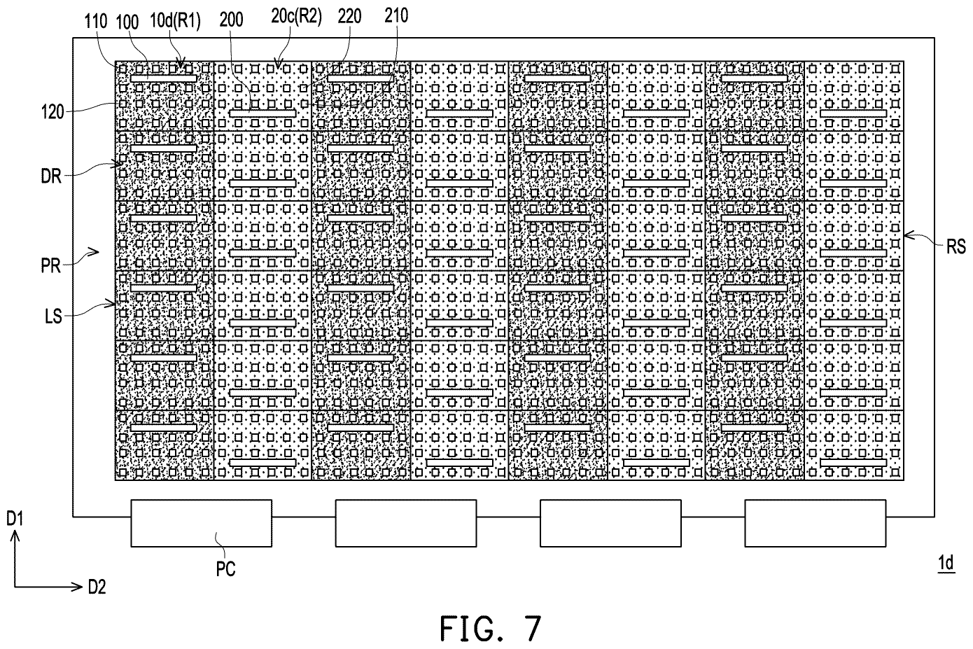

FIG. 7 is a schematic top view of a display device 1d according to a fourth embodiment of the disclosure. The display device 1d is different from the display device 1a of the first embodiment in that the shapes of a portion of the control regions within the display region DR are different.

With reference to FIG. 7, in this embodiment, the display region DR of the display device 1d includes a plurality of first control regions R1 and a plurality of second control regions R2.

In this embodiment, the first control regions R1 are arranged in a plurality of columns in the first direction D1 in the display region DR, and the second control regions R2 are arranged in a plurality of columns in the first direction D1. The first control regions R1 and the second control regions R2 are arranged in an alternating manner in the second direction D2.

In this embodiment, the first control regions R1 and the second control regions R2 are both rectangular. The first light-emitting units 10d are disposed on the first control regions R1. The specific structure of the first light-emitting units 10d may be found with reference to FIG. 6C and related description. The second light-emitting units 20c are disposed on the second control regions R2. The specific structure of the second light-emitting units 20c may be found with reference to FIG. 6B and related description.

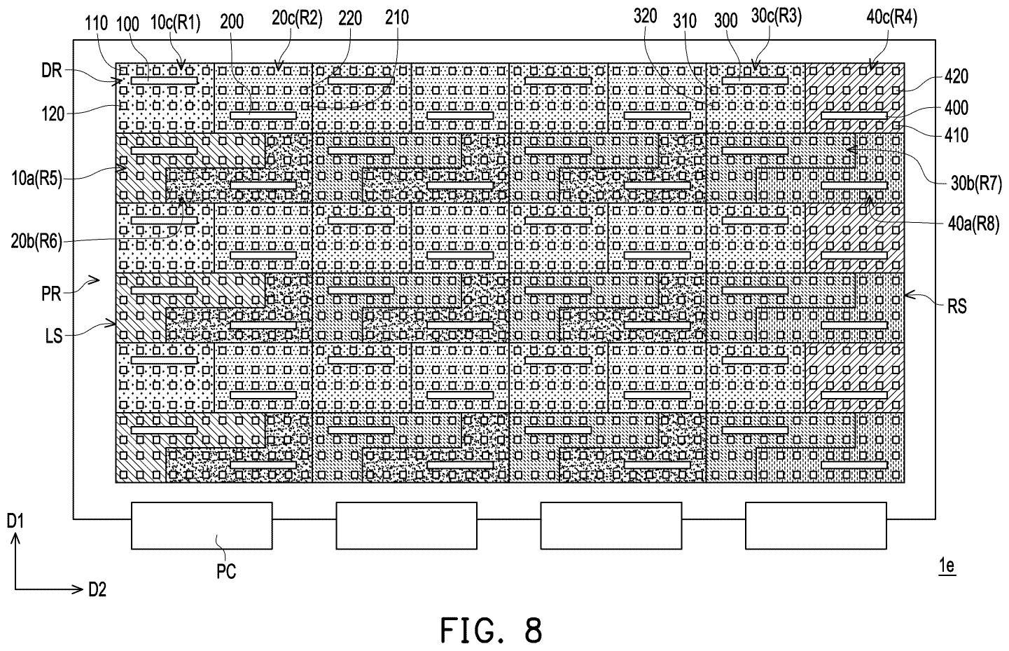

FIG. 8 is a schematic top view of a display device 1e according to a fifth embodiment of the disclosure. The display device 1e is different from the display device 1a of the first embodiment in that the shapes of a portion of the control regions within the display region DR are different.

With reference to FIG. 8, in this embodiment, the display region DR of the display device 1e includes a plurality of first control regions R1, a plurality of second control regions R2, a plurality of third control regions R3, a plurality of fourth control regions R4, a plurality of fifth control regions R5, a plurality of sixth control regions R6, a plurality of seventh control regions R7, and a plurality of eighth control regions R8.

In this embodiment, the first control regions R1 and the fifth control regions R5 are arranged in an alternating manner in the first direction D1. The second control regions R2 and the sixth control regions R6 are arranged in an alternating manner in the first direction D1. The third control regions R3 and the seventh control regions R7 are arranged in an alternating manner in the first direction D1. The fourth control regions R4 and the eighth control regions R8 are arranged in an alternating manner in the first direction D1.

The first control regions R1 and the fifth control regions R5 are arranged along the first side LS of the display region DR. The fourth control regions R4 and the eighth control regions R8 are arranged along the second side RS of the display region DR. The second control regions R2 and the third control regions R3 are disposed between the first control regions R1 and the fourth control regions R4. The second control regions R2 and the third control regions R3 are arranged in an alternating manner in the second direction D2. The sixth control regions R6 and the seventh control regions R7 are disposed between the fifth control regions R5 and the eighth control regions R8. The sixth control regions R6 and the seventh control regions R7 are arranged in an alternating manner in the second direction D2.

In this embodiment, the first control regions R1, the second control regions R2, the third control regions R3, and the fourth control regions R4 are all rectangular. The first light-emitting units 10c, the second light-emitting units 20c, the third light-emitting units 30c, and the first light-emitting units 40c are respectively disposed on the first control regions R1, the second control regions R2, the third control regions R3, and the first control regions R4. The specific structures of the first light-emitting units 10c, the second light-emitting units 20c, the third light-emitting units 30c, and the fourth light-emitting units 40c may be found with reference to FIG. 5, FIG. 6A to FIG. 6C, and related description.

In this embodiment, the fifth control regions R5, the sixth control regions R6, the seventh control regions R7, and the eighth control regions R8 are all L-shaped. The first light-emitting units 10a (also referred to as the fifth light-emitting units in this embodiment), the second light-emitting units 20b (also referred to as the sixth light-emitting units in this embodiment), the third light-emitting units 30b (also referred to as the seventh light-emitting units in this embodiment), and the fourth light-emitting units 40a (also referred to as the eighth light-emitting units in this embodiment) are respectively disposed on the fifth control regions R5, the sixth control regions R6, the seventh control regions R7, and the eighth control regions R8. The specific structures of the first light-emitting units 10a, the second light-emitting units 20b, the third light-emitting units 30b, and the fourth light-emitting units 40a may be found with reference to FIG. 2A, FIG. 2C, FIG. 3, FIG. 4, and related description.

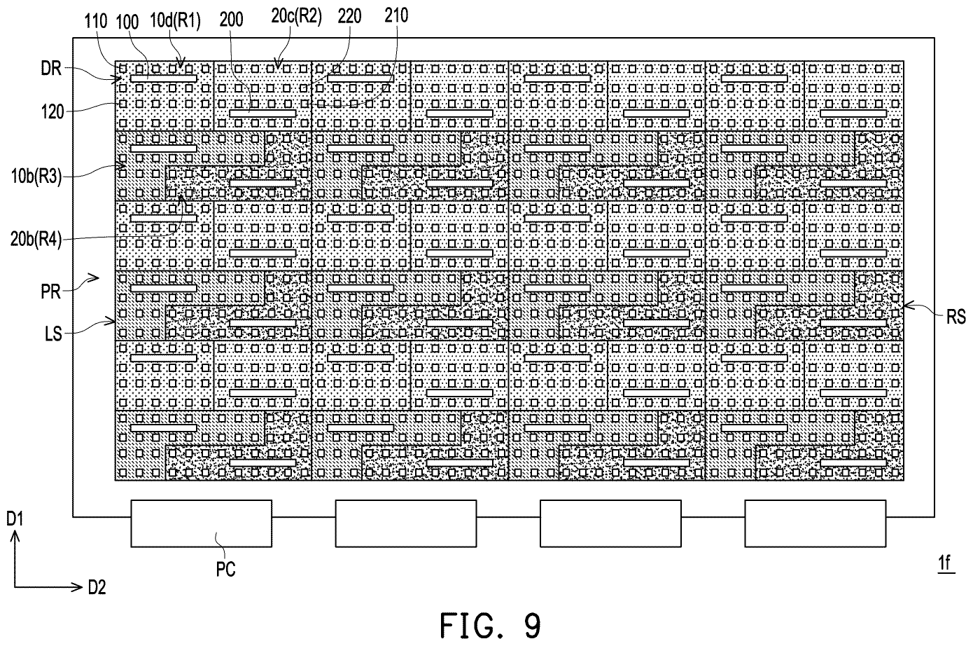

FIG. 9 is a schematic top view of a display device 1f according to a sixth embodiment of the disclosure. The display device If is different from the display device 1a of the first embodiment in that the shapes of a portion of the control regions within the display region DR are different.

With reference to FIG. 9, in this embodiment, the display region DR of the display device If includes a plurality of first control regions R1, a plurality of second control regions R2, a plurality of third control regions R3, and a plurality of fourth control regions R4.

In this embodiment, the first control regions R1 and the third control regions R3 are arranged in an alternating manner in the first direction D1, and the second control regions R2 and the fourth control regions R4 are arranged in an alternating manner in the first direction D1. The first control regions R1 and the second control regions R2 are arranged in an alternating manner in the second direction D2, and the third control regions R3 and the fourth control regions R4 are arranged in an alternating manner in the second direction D2.

In this embodiment, the first control regions R1 and the second control regions R2 are both rectangular. The first light-emitting units 10d and the second light-emitting units 20c are respectively disposed on the first control regions R1 and the second control regions R2. The specific structures of the first light-emitting units 10d and the second light-emitting units 20c may be found with reference to FIG. 5, FIG. 6B, FIG. 6C, and related description.

In this embodiment, the third control regions R3 and the fourth control regions R4 are both L-shaped. The first light-emitting units 10b (also referred to as the third light-emitting units in this embodiment) and the second light-emitting units 20b (also referred to as the fourth light-emitting units in this embodiment) are respectively disposed on the third control regions R3 and the fourth control regions R4. The specific structures of the first light-emitting units 10b and the second light-emitting units 20b may be found with reference to FIG. 2C, FIG. 4, and related description.

In view of the foregoing, by designing the supplementary pixels, even if the microcontrollers are arranged in an alternating manner, the pixels may be neatly arranged at the edge of the display region, so that jagged edges are prevented from appearing on the display screen. Through arrangement of the supplementary pixels, the display region may be maximized, so that the display device may exhibit an improved display effect.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display device, comprising:
a driver substrate having a display region and a peripheral region; and
a first light-emitting unit disposed on the driver substrate and comprising:
a first microcontroller disposed on the display region and electrically connected to the driver substrate through a plurality of first connection pads; and
a plurality of first pixels and a plurality of first supplementary pixels electrically connected to the first microcontroller and disposed on the display region, wherein the first pixels are arranged in two rows extending in a second direction in a first direction, and the first supplementary pixels are arranged in two other rows extending in the second direction in the first direction, wherein the first microcontroller is disposed between the first pixels in the two rows in the first direction, and the first supplementary pixels in the two other rows are at least partially aligned with the first pixels in the two rows in the first direction.

2. The display device according to claim 1, wherein the first light-emitting unit further comprises:
a plurality of first traces completely disposed in the display region and electrically connecting the first microcontroller to the first pixels in the two rows; and
a plurality of first supplementary traces completely disposed in the display region and electrically connecting the first microcontroller to the first supplementary pixels in the two other rows.

3. The display device according to claim 1, wherein the first light-emitting unit further comprises:
a plurality of first traces completely disposed in the display region and electrically connecting the first microcontroller to the first pixels in the two rows; and
a plurality of first supplementary traces, wherein at least a portion of the first supplementary traces extend from the first microcontroller in the display region to the peripheral region and then extend from the peripheral region to the first supplementary pixels in the two other rows in the display region.

4. The display device according to claim 3, wherein another portion of the first supplementary traces are completely disposed in the display region.

5. The display device according to claim 1, wherein the display region comprises a plurality of first control regions, and the display device further comprises a plurality of first light-emitting units, wherein the first microcontroller, the first supplementary pixels, and the first pixels in each of the first light-emitting units are disposed on a corresponding one among the first control regions, wherein the first control regions are aligned in the first direction at a boundary between the display region and the peripheral region.

6. The display device according to claim 1, further comprising a plurality of first light-emitting units, wherein in each of the first light-emitting units, a vertical projection of the first microcontroller on the driver substrate does not overlap with vertical projections of the first pixels and the first supplementary pixels on the driver substrate.

7. The display device according to claim 1, further comprising:
a plurality of second light-emitting units disposed on the driver substrate and arranged in the first direction, wherein each of the second light-emitting units comprises:
a second microcontroller disposed on the display region and electrically connected to the driver substrate through a plurality of second connection pads; and
a plurality of second pixels electrically connected to the second microcontroller and disposed on the display region, wherein the second pixels are arranged in two rows extending in the second direction in the first direction, wherein the second microcontroller is disposed between the second pixels in the two rows in the first direction.

8. The display device according to claim 7, further comprising a plurality of first light-emitting units, wherein the first microcontrollers of the first light-emitting units and the second microcontrollers of the second light-emitting units are arranged in an alternating manner in the first direction.

9. The display device according to claim 7, wherein the display region comprise a plurality of first control regions and a plurality of second control regions, and the display device further comprises a plurality of first light-emitting units, wherein the first microcontroller, the first supplementary pixels, and the first pixels in each of the first light-emitting units are disposed on a corresponding one among the first control regions, and the second microcontroller and the second pixels in each of the second light-emitting units are disposed on a corresponding one among the second control regions, wherein a width of each of the first control regions in the first direction is twice a width of each of the second control regions in the first direction.

10. The display device according to claim 7, wherein each of the second light-emitting units comprises:
a plurality of second supplementary pixels electrically connected to the second microcontroller and disposed on the display region, wherein the second supplementary pixels are arranged in two other rows extending in the second direction in the first direction, wherein the second supplementary pixels in the two other rows are at least partially aligned with the second pixels in the two rows in the first direction.

11. The display device according to claim 10, wherein the display region comprise a plurality of first control regions and a plurality of second control regions, and the display device further comprises a plurality of first light-emitting units, wherein the first microcontroller, the first supplementary pixels, and the first pixels in each of the first light-emitting units are disposed on a corresponding one among the first control regions, and the second microcontroller, the second pixels, and the second supplementary pixels in each of the second light-emitting units are disposed on a corresponding one among the second control regions, wherein a width of each of the first control regions in the first direction is equal to a width of each of the second control regions in the first direction.

12. A display device, comprising:
a driver substrate having a display region and a peripheral region; and
a first light-emitting unit disposed on the driver substrate and comprising:
a first microcontroller disposed on the display region and electrically connected to the driver substrate through a plurality of first connection pads;
a plurality of first pixels disposed on the display region and arranged in two rows extending in a second direction in a first direction;
a plurality of first supplementary pixels disposed on the display region and arranged in two other rows extending in the second direction in the first direction;
a plurality of first traces completely disposed in the display region and electrically connecting the first microcontroller to the first pixels in the two rows; and
a plurality of first supplementary traces, wherein at least a portion of the first supplementary traces extend from the first microcontroller in the display region to the peripheral region and then extend from the peripheral region to the first supplementary pixels in the two other rows in the display region.
